(19) United States
(12) Patent Application Publication
(10) Pub. No.: US 2017/0339000 A1
(43) Pub. Date: Nov. 23, 2017

(54) REMOTE CONTROLLED LED BASED ID EMITTER

(71) Applicant: BASIC6 INC., Westport, CT (US)

(72) Inventors: Magnus WENNEMYR, Amherst, MA (US); Edward SAMSON, Weston, CT (US)

(21) Appl. No.: 15/599,614

(22) Filed: May 19, 2017

Related U.S. Application Data
(60) Provisional application No. 62/338,815, filed on May 19, 2016.

(51) Int. Cl. H04L 29/08; H01L 27/32; G06F 9/46; G06F 9/22

(52) U.S. Cl. CPC H04L 29/08099; G06F 9/226; H01L 27/32; H04L 67/10; G06F 9/223; G06F 9/467; G08C 2201/93; G08C 2201/42

(57) ABSTRACT

An apparatus includes a luminaire; power input for the luminaire; a modulation circuit for modulating the power input so that light output includes an identifier of the luminaire; and a programmable memory for storing at least one of the identifier of the luminaire and a modulation scheme for modulation of the luminaire to place a signal on the light. A method for modulating light includes storing in programmable memory an identifier for the luminaire, the identifier being used to modulate the light, and/or a modulation scheme for modulation of the luminaire; and changing content of programmable memory to change the identifier and/or the modulation scheme. A method of efficiently deploying the luminaires and identifying their locations to a network is disclosed. A method of multi-factor authentication using authentication data transmitted by modulating the light emitted by a luminaire is also disclosed.

This application claims priority from and the benefit of provisional application Ser. No. 62/338,815 filed on May 19, 2016, which is incorporated herein by reference, in its entirety, for all purposes.

### BACKGROUND OF THE DISCLOSURE

### 1. Field of the Disclosure

The present disclosure relates to the Internet of Things (IoT). The IoT is essentially the set of connectable and identifiable electronic devices that are being installed in our surroundings at an increasing rate. This disclosure also relates to the technology of light-emitting diodes (LED), semi-conductor based lighting, that has many advantages over incandescent light sources including lower energy consumption, longer lifetime, improved physical robustness, smaller size, and faster switching.

### 2. Description of the Related Art

This application is related to patent application Ser. No. 14/671,694 filed on Mar. 27, 2015, published as United States Patent Publication No. 2015/0281337, which claims priority from and the benefit of provisional patent application Ser. No. 61/972,754, filed on Mar. 31, 2014. This application is also related to provisional patent application Ser. No. 62/274,619, filed on Jan. 4, 2016 and provisional patent application Ser. No. 62/303,914 filed on Mar. 4, 2016. These applications are incorporated herein by reference, in their entirety, for all purposes.

With the IoT “smart” devices have proliferated. These devices are capable of a greater range of functionality and communication. The way such devices operate is typically with a microcontroller (MCU)-based program that collects data about and controls its environment via sensors and actuators. Smart devices include WiFi or other communication modes, and sometimes even include an external microprocessor (MPU) running full-fledged operating systems that greatly extend the device's capabilities. The devices may communicate with each other, and via a gateway, both receive controls from and send data to a customer's data store over the internet.

It is the capability of LEDs that enables light to be used as a medium over which data can be communicated from LEDs to light-sensitive receivers. In its simplest form, this visible light communication (VLC) works by switching the LEDs off and on at a very high rate using a modulator circuit. An LED may be used to emit a repeated uniquely identifying pattern, an “ID”, which can be used by a receiving device in the path of the light to pinpoint the receiver's location. This ID is imprinted on a device during manufacture so as to be identifiable globally, typically in the form of a 48-bit MAC address assigned to firmware on a microcontroller, where a MAC address is the standard unique identifier assigned to physical network interfaces. The “imprint” may be considered to consist of both the scheme by which the data is modulated, as well as the ID itself. The terms VLC and LiFi are both sometimes used to describe communication of data by blinking an LED in any fashion, irrespective of whether there exists a bidirectional capability. The ID emitted by the LED will herein be referred to as the “VLC ID”.

Provisional Patent Application Ser. No. 62/274,619, filed on Jan. 4, 2016, entitled Adapter Extending Capabilities of Remote Control and LiFi To Installations of Light-Emitting Diode-Based Luminaires describes the environment for use of the embodiments disclosed herein, where LiFi and remote control are added to the luminaire containing the LED and driver. The circuits disclosed herein also can be added.

The inventors herein have determined that a number of problems are introduced when the ID is imprinted on a device during the manufacturing stage. The first of these listed below is potentially critical for a system to function well, whereas the remaining problems speak to either convenience to a customer or to an increase in complexity in other parts of the system.

1. To receive the VLC ID, special devices containing a photodiode or other type of light sensor or sensors may be constructed and deployed on objects whose location is of interest. Such configurations have been demonstrated to be capable of transmitting data at high speeds (above 100 MHz). Alternatively, mobile phones that do not contain light sensors appropriate for this type of application but that embed a camera with a rolling shutter mechanism may use the camera instead. In the latter case, the rate of data transmission receivable is limited by factors related to the image capture frequency, and the speed of the rolling shutter of the camera. Camera-based solutions typically yield transmit rates only in the 2 to 8 kHz range. In the absence of specialized receivers, the limitation imposed by the latter for mobile phone based applications is significant. As a consequence, individual images often do not suffice to capture an entire ID. In this case, to capture entire IDs, multiple images must be captured using the video capability of the cameras, and the resulting images made to overlay one another to form a time-panoramic view from which the entire ID may be extracted. The complexity of required software is increased, and the robustness with which the ID can be extracted is reduced.

2. The emission of a VLC ID may be considered a service for which a customer (the owner of a store, e.g.) pays. As contracts begin and end, it is desirable for the service to commence and cease. This cannot be performed easily except by flashing the firmware of each modulator on each light fixture, which is laborious and for which a physical entryway into the modulating circuitry would have to be provided.

3. Once VLC ID emitting light fixtures have been placed, it is difficult to accommodate changes that rely on increasing or decreasing the density of ID emissions, for instance to avoid interference between lights, as may be beneficial to applications that leverage the capability.

4. Applications cannot leverage any communication from the VLC ID other than that provided by its static nature. If it could change in real time, additional information can be delivered, such as a dedicated ID that signals an emergency.

5. In a scenario where lights are re-deployed to a different location, data collected from an application that receives its information based on the ID before the move cannot easily be distinguished from data collected after the move, as might be desired given its new context. A similar issue occurs when a light fixture has to be replaced: the VLC ID of the new device will not match the old device, which complicates data store logical relationships and increases application complexity.

6. Should improvements to the modulation scheme itself be discovered, improvements to lights already deployed cannot be made except by flashing the firmware of each corresponding modulator, which is laborious and for which a physical entryway into the modulating circuitry would have to be provided.

7. Deployment of networked, addressable, lights where the precise location of the lights is of interest can be laborious. The locations of the lights need to be assigned along with a mapping to the corresponding network address. When an ID is fixed, typically for the purpose of enabling pinpointing of the location of a receiver, from the time it is assigned, it cannot also be used effectively to propagate other information that could otherwise be used to provide aid during the deployment phase.

### SUMMARY OF THE DISCLOSURE

The issue of reduced receivable bandwidth by camera-based applications calls for transmission of as limited an amount of data as possible embedded in the VLC ID. This allows fewer images to be used in determining the ID, and at times only a single image, greatly reducing software complexity, and increasing the accuracy of the estimate of the ID (robustness). To aid in this endeavor, it is possible to transmit a significantly shorter ID (instead of a globally unique ID) that is unique enough that each LED can be distinguished from every other within any one deployment locale. To do this, it is either necessary to predict at manufacturing time which ID-emitting LED will be deployed where, or alternatively to provide a mechanism whereby the ID may be modified at a later time.

A method has therefore been invented whereby each VLC-capable LED is connected to a console where the ID may be set at the time of deployment, or any time thereafter. A managerial user may assign and distribute unique IDs to all lights within the deployment, where an ID of any length appropriate to the deployment may be specified. For instance, a 16 bit ID may be used to support 64 k unique lights for a larger deployment, while shorter IDs can be used to support smaller deployments. For instance, in a home 6 bits may be sufficient, supporting 64 unique IDs. The console software supports a mechanism whereby all connected lights can have unique IDs all assigned at the same time by the software, or where individual lights may be selected for individual assignment. Similarly, over a given time-period, more individual ID readings can be made for a more robust, less error-prone, interpretation of the intended signal.

The disclosed method by which IDs may be modified post-deployment has the additional benefit of allowing the emission of IDs to be halted altogether (for instance by clearing the ID), or recommenced upon request.

Should post-deployment testing indicate interference by one light over another for any reason, emission of one or more particular VLC IDs may be modified or stopped.

Applications built in accordance with this disclosure, on the possibility that IDs may be changed at any time, can effectively broaden the range of features that can be built on additional data that may be transmitted.

Re-deployments of existing fixtures can be accompanied by a change in ID as desired to reflect the change to historical data stores, and replacement of impaired lights become as easy as the initial deployment when the new light may be assigned the ID of the light it is replacing. No record keeping of IDs is required in such cases. Manufacturing complexity is reduced since all lights can be created without consideration of IDs, and application data stores do not need to be manipulated.

The disclosure also addresses upgrades to modulation schemes by allowing not only the replacement of VLC IDs, but also the remainder of the firmware that controls how the signal is modulated.

The disclosure also describes how a modifiable VLC ID can be used to shorten deployment time and complexity of networked, addressable, lights by changing the ID to mimic the networking address of a given light. By detecting the emitted ID using a deployment application on a mobile phone or tablet, the networking address of each light is known in a fashion that allows a worker to walk a floor under the networked lights and map the floor without accessing the hardware. Since the carrier light of the ID is recognizable by the human eye, the worker knows which light their receiver device captures in an intuitive fashion with great certainty.

In general, the disclosure is directed to an apparatus comprising a luminaire; a power input for the luminaire; a modulation circuit for modulating the power input to the luminaire so that light output of the luminaire includes an identifier of the luminaire; and a programmable memory within the modulation circuit for storing at least one of the identifier of the luminaire and a modulation scheme for modulation of the luminaire to place a signal on light emitted by the luminaire.

The identifier is generally in the form of digital information. In general, the apparatus is used in combination with a number of other similar apparatus at a given location, wherein the digital information of the identifier includes a sufficient number of bits so that each apparatus has a unique identifier. The number of bits can be selected to be no larger than required so that the identifier includes a sufficient number of bits for each apparatus to have a unique identifier.

The apparatus can further comprise a communications circuit for communication between the modulation circuit and an external platform, so that the external platform can perform at least one of storing the identifier, and communicating with the modulation circuit to perform at least one of providing the identifier to the apparatus, changing the identifier of the apparatus, removing the identifier of the apparatus and modifying the modulation scheme. The modifying of the modulation scheme can include at least one of turning on modulation with the identifier, turning off modulation with the identifier, changing an encoding or encryption scheme of the modulation, or changing the modulation scheme itself to one of many known or custom prepared modulation schemes (e.g. OFDM, OOK, PPM) or parameters thereof.

The modulation circuit can include at least one microcontroller. The power input to the luminaire can include a constant current source. The luminaire can comprise a light emitting diode.

In general, this disclosure is directed to a method for modulating light from a luminaire, comprising storing in a programmable memory at least one of an identifier for the luminaire, the identifier being used to modulate the light, and a modulation scheme for modulation of the luminaire; and changing content of the programmable memory to change at least one of the identifier and the modulation scheme.

Again, the identifier is generally in the form of digital information. In general, the apparatus is used in combination with a number of other similar apparatus at a given location, wherein the digital information of the identifier includes a sufficient number of bits so that each apparatus has a unique identifier. The number of bits can be selected to be no larger than required so that the identifier includes a sufficient number of bits for each apparatus to have a unique identifier.

The method can further comprise the luminaire communicating with an external platform, so that the external platform can perform at least one of storing the identifier, providing the identifier to the luminaire, changing the identifier of the luminaire, removing the identifier of the luminaire and modifying the modulation scheme.

Modifying the modulation scheme can include at least one of turning on modulation with the identifier, turning off modulation with the identifier, changing any encoding or encryption scheme of the modulation, or changing the modulation scheme itself to one of many known or custom prepared modulation schemes (e.g. OFDM, OOK, PPM) or parameters thereof.

In accordance with the method, the power input to the luminaire can include a constant current source. The luminaire can comprise a light emitting diode.

The disclosure is also directed to a method for programming modulation circuitry of luminaires at a location, comprising selecting a number of identification bits required so that all luminaires have a unique identifier; registering the luminaires so that each luminaire has one of the unique identifiers; and providing the number of identification bits and modulation scheme and parameters to a receiver so that the receiver can recognize the identifiers.

In one embodiment, the number of bits is no larger than required so that the identifier includes a sufficient number of bits for each luminaire to have a unique identifier.

The disclosure is also directed to a method of mapping the locations of a plurality of visible light communication devices capable of attaching to a network, comprising deploying the plurality of devices by networking the devices and assigning to each of the plurality of devices a network addresses; registering the plurality of devices with and connecting the plurality of devices to a remote computing system from which the plurality of devices is controlled; placing the plurality of devices in physical locations; utilizing the remote system to instruct the plurality of devices to emit modulated light with an identification corresponding to the network address; using a light receiver to receive the modulated light from each of the plurality of devices; converting the modulated light from each of the plurality of devices to a plurality of digital signals; processing each of the plurality of the digital signals to determine the identity of each of the plurality of devices; associating each identity with the physical location of a corresponding device; and storing the identities, and locations corresponding to the identities, in a memory.

The method can comprise associating each of the physical locations with a place on a map containing the physical locations.

The light receiver can be a camera. The camera can be located in a mobile telephone. An application on a mobile telephone can be used to associate positions on a map with the physical locations. The map can be displayed on the mobile telephone. The light receiver can be an optical sensor.

The plurality of devices can be manufactured without specific identifications and without specific network addresses. Security credentials can be exchanged between the plurality of devices and the remote system.

The method can further comprise disposing and orienting the light receiver to successively receive identities from a series of devices. The devices can be provided with identifiers before or after the devices are deployed.

The disclosure is also directed to a method for authenticating a user of a device or system, comprising receiving, from the user, first authentication data; receiving from a luminaire providing modulated light, second authentication data represented by modulation of the modulated light; recovering from the modulated light the second authentication data; and authenticating the user only when the first authentication data and the second authentication data are recognized as being authentic. Some authenticating systems may require additional authentication data, and some authentication systems may require only the second authentication data. It is the delivery mechanism of the light ID as proxy for the physical light that establishes that receipt of the ID by a receiver to verify that the receiver is in fact in proximity of the light itself that is a significant aspect of the disclosure.

The second authentication data is generated by a first code calculating engine associated with the authenticating device or system and may be also generated by a matching second code calculating engine associated with the luminaire. The second authentication data is considered to be authentic when the authentication data generated by the first code calculating engine and the authentication data generated by the second code calculating engine are identical. Alternatively, the luminaire may not contain a code calculating engine in which case the second authentication data may instead be delivered to the luminaire over a communication channel from the system associated with the first code calculating engine after which it is used to modulate the light emitted by the luminaire. In this latter case, the secret data generated by the first code calculating engine may be as simple as a random number.

The method can further comprise sharing secret data between the first code generating engine and the second code generating engine to generate the second authentication data by both engines. Time can be used along with the secret data as inputs to the code calculating engines in generating the output authentication data. The shared secret data can be any unique sequence of bits generated by the first code generating engine. Thus, the second authentication data can be generated by one of the first code calculating engine and the second code calculating engine.

The device or system can be in continuous or intermittent communication with the luminaire, or limited to a single communication consisting solely of the exchange of secret data sufficient to generate future codes to be compared. It is possible for the exchange of secret data to be carried out during the manufacturing process or at a later stage, and the code calculating engine may be fully expressed in hardware as well as software.

### BRIEF DESCRIPTION OF THE DRAWINGS

FIG. 1 is a simplified system diagram wherein a luminaire sends a signal to a receiver and data is carried to and from the luminaire.

FIG. 2 is a system diagram that shows circuits disclosed herein being managed from a device management platform.

FIG. 3 is a simplified schematic diagram of a circuit, including its environment that provides capability of changing VLC ID.

FIG. 4 is a more detailed schematic diagram of a circuit that provides capability of changing VLC ID.

FIG. 5 illustrates a first step in deploying luminaires as disclosed herein.

FIG. 6 illustrates a second step in deploying luminaires as disclosed herein.

FIG. 7 illustrates a third step in deploying luminaires as disclosed herein.

FIG. 8 is an illustration of the manner in which device identification information can be acquired during deployment of the devices.

FIG. 9 is an illustration of the manner in which the concepts disclosed herein can be used for multifactor authentication.

FIG. 10 illustrates an authentication scenario for a stand-alone device.

FIG. 11 illustrates an authentication scenario for a connected device.

A component or a feature that is common to more than one drawing is indicated with the same reference number in each of the drawings.

### DESCRIPTION OF THE EMBODIMENTS

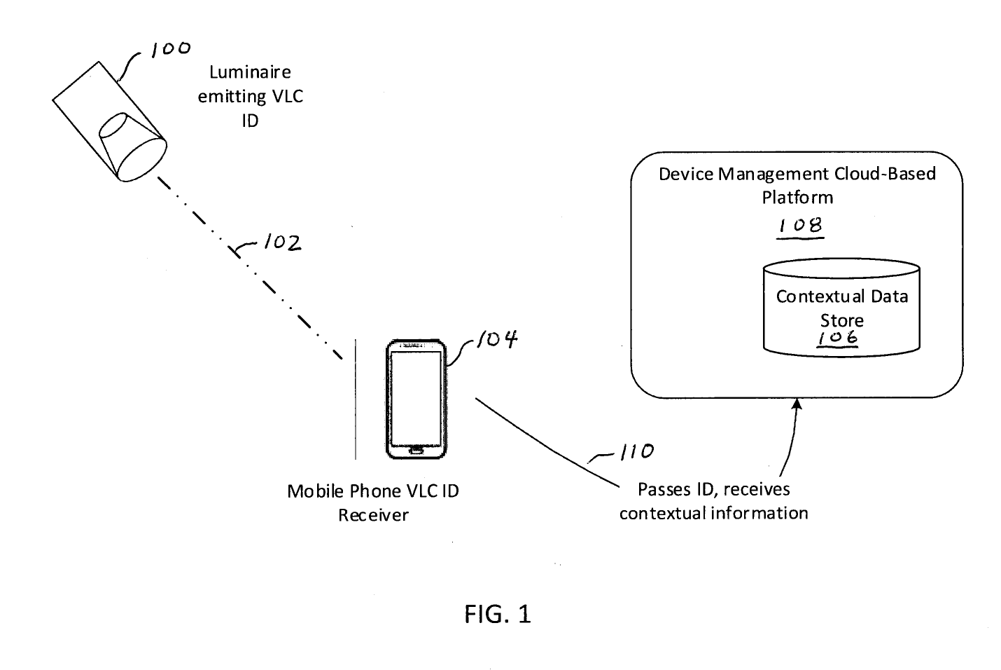

In FIG. 1, an embodiment a luminaire 100 repeatedly emits a signal transported over light 102, while a receiver 104 (such as, for example, a receiving mobile phone) interprets the signal carried by light 102, which may be visible light. The VLC ID of luminaire 100 so discerned may be passed to a networked data store 106, in a device management cloud based platform 108, via a network connection 110, in order to retrieve contextual information associated with the luminaire's ID, such as the location of the luminaire, from which may be inferred the approximate location of the receiver 104.

It possible to utilize non-visible spectra (infrared or ultraviolet) for transmitting the VLC ID and other information. Similarly, it is not strictly necessary for the emission of light to be carried out from a light fixture; it could be any container of circuitry and a light-emitting diode. The receiver 104 need not be in the form of a mobile phone, but could be any light-sensitive device capable of demodulating the emitted signal, whether or not connected to a larger network.

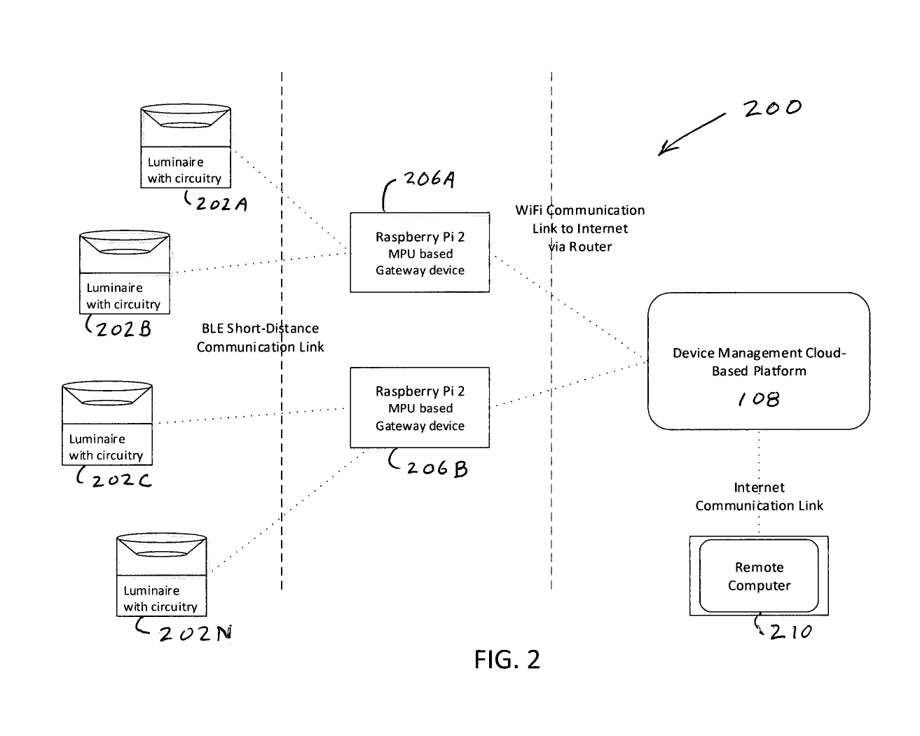

In FIG. 2, the various embodiments are placed in context of a related system 200 whereby data can be collected from and control is exerted over remotely placed luminaire devices 202A, 202B, 202C . . . 202N (each device including, for example, a luminaire, an adapter of the type described in the abovementioned provisional application Ser. No. 62/274,619 filed on Jan. 4, 2016, and a power supply or a connection thereto), from device management platform 108. Device management platform 108, which can be cloud based, can include a sensor readings database. Only key portions of the entire network devices are depicted, not including, for instance, routers, here exemplified by internet addressable Raspberry Pi 2 devices acting as gateways 206A, 206B. Platform 108 communicates with the one or more gateway devices 206A, 206B, etc. using, for example, the websockets protocol. The gateway devices 206A, 2606B, in turn communicate with one or more adapters of devices 202A, 202B, 202C . . . 202N using, for example, the MQTT protocol or a BLE short-distance communications link. Software agents developed by Basic6 (of the type described in application Ser. No. 14/671,694 filed on Mar. 27, 2015, and published as United States Patent Publication No. 2015/0281337) on the internet-addressable gateway devices 206A, 206B, are capable of maintaining full duplex websocket communication channels for real-time control of the remote devices, routing that information to the correct end-point adapter over MQTT protocol or BLE short-distance communication link, receiving sensor readings, making control decisions rooted in the algorithms of the resident software, exerting the relevant controls corresponding to those decisions, and delivering sensor readings to cloud-based services. In this manner, the network of the luminaire devices 202A, 202B, 202C . . . 202N is not directly connected to, nor accessible from, the internet.

A user driving the device management platform 108, via a computer 210 can view the sensor readings and the status of the luminaire devices and associated sensors, and can exercise control of all or a subset of the luminaire devices 202A, 202B, 202C . . . 202N, acting on the subset as a whole. A user can also determine status of and exercise control over the gateway devices 206A, 206B. The ability to control the luminaire devices 202A, 202B, 202C . . . 202N includes replacing the software on them remotely, and to deliver security tokens used for secure communications to the luminaire devices 202A, 202B, 202C . . . 202N, as also described in application Ser. No. 14/671,694 filed on Mar. 27, 2015, and published as United States Patent Publication No. 2015/0281337. Replacing the software is discussed below.

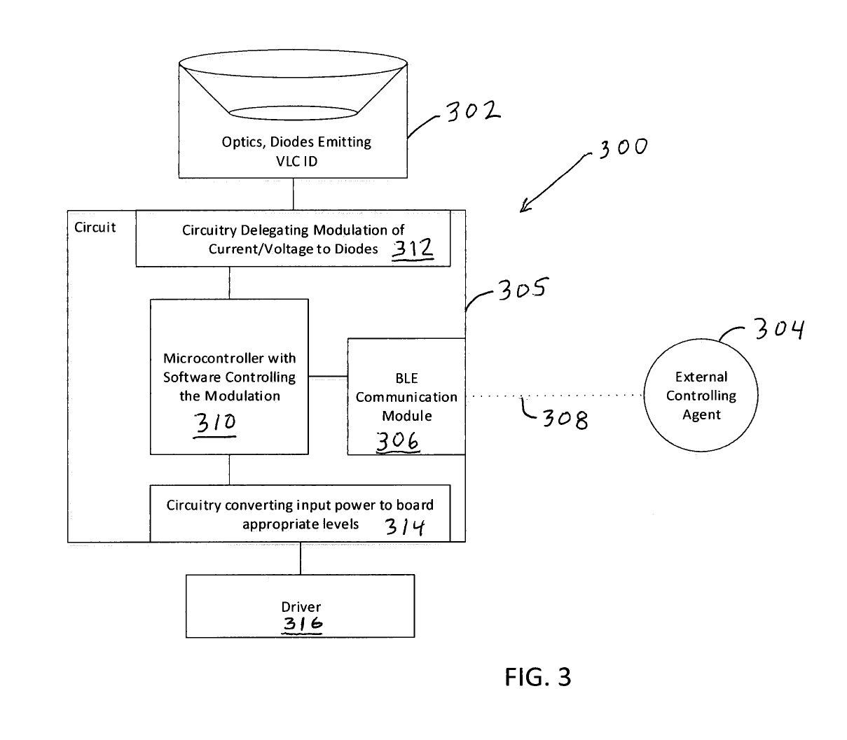

In FIG. 3, the relevant parts of a luminaire device 300 are depicted in its immediate environment, including a luminaire 302 and an external agent 304 to control the VLC ID. An electronic circuit 305 includes a BLE communication module 306 that is capable of receiving instructions and delivering luminaire status over a network 308 (depicted by dashed lines). The instructions sent to the circuit 306 in turn modify the behavior of the software of a microcontroller 310 to change electrical outputs that control circuitry 312 that cause LEDs of the luminaire 302 to emit the commensurate signal. Microcontroller 310 will have associated memory for storing the software, and the associated instructions, for implementing a modulation scheme, and for storing the VLC ID. Power circuitry 314 converts the power delivered by the power supply (“driver” 316), to circuit board appropriate DC levels.

In the embodiments described below, the communication module is of a particular variety, and the decision and modulation-capable components a combination of two microcontrollers. These specifics are merely examples, and may be replaced by components that perform equivalent tasks. The workings of the circuitry may be replaced by circuitry that performs the basic functions of receiving updates from a remote agent, delivering those updates to the circuit components, and modifying the modulation scheme and VLC ID accordingly.

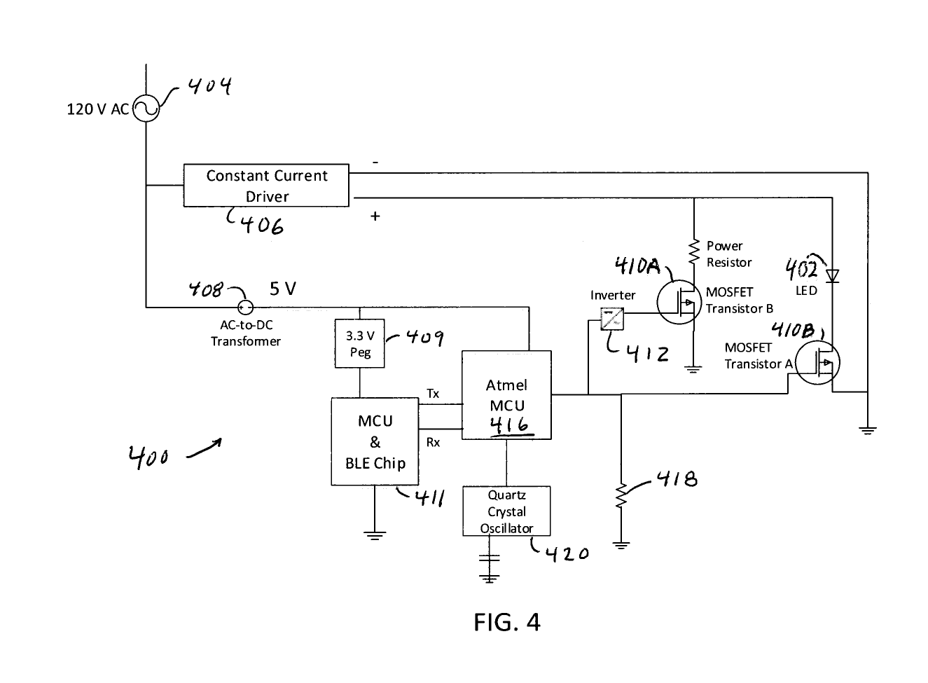

In FIG. 4, the circuit of the previous figure is depicted in greater detail as circuit 400 and is slightly simplified for purposes of illustration. The basic components of the LED 402 of the luminaire, mains power 404, a constant current driver 406 for the LED 402 (of the type disclosed in the abovementioned provisional patent application Ser. No. 62/303,914, an AC-to-DC transformer 408 appropriate for powering the other components. The other components are for managing communication and remote control of the luminaire device as well as the modulation of the LED 402. An 3.3 volt regulator provides power for an MCU 411, having an associated BLE chip as discussed below.

Modulation is accomplished by controlling from the same MCU-regulated output voltage the current through these components with the combination of two MOSFET transistors 410A and 410B. However, the input voltage to transistor 410A is controlled by an inverter 412. Inverter 412 acts to switch the voltage at the gate of MOSFET transistor 410A high when the output of an Atmel MCU 416 is low, and low when the output of the MCU 416 is high. Accordingly, the gate voltages at transistors 410A and 410B will always be opposite high and low at any one time, allowing current to flow through either one of the two legs attached to driver 406. Current flowing through power resistor 418 is dissipated in the form of heat. A small leakage current may flow through LED 402 when transistor 410B is otherwise off.

The external agent (FIG. 3, 304) networks with the circuit via Bluetooth v 4.0 (BLE), where the device includes a BLE chip, as exemplified in more detail below. It is equally possible to connect to the luminaire device using WiFi or ZigBee or Thread or cellular chips, via a direct Ethernet connection, Ethernet over power, or other means to communicate with a network. The circuit board's Bluetooth chip is in this case configured to connect to a gateway that provides a communication channel to the broader internet, over which control of the circuit can be exerted, but could also be connected directly to the internet via a router.

MCU 411, having an associated BLE chip, is programmed with software to manage communication interaction and logic, and to communicate control signals to the Atmel MCU 416. The purpose of the latter microcontroller, which is provided with a crystal quartz oscillator 420 to provide a stable clock cycle, is to run software dedicated to outputting the desired modulation in a stable fashion by generating a voltage output to the gate of transistor 410B. The exact types and combination of two microcontrollers is merely exemplary, and may be replaced by components that perform equivalent tasks using single, multiple or other microcontroller and/or microprocessor chips that manage communication and the modulation of the signal, chosen according to various performance requirements such as the frequency at which modulation is to occur.

The type of driver and exact circuitry to mediate control of the LED according to the instructions within the MCU is merely exemplary. What is important is the capacity to replace the VLC ID in real-time. When the latter is desired, a communication is made to the MCU or MCUs that regulates or changes the nature of the signal modulation, upon which it alters its output accordingly.

An important aspect of the disclosed embodiment is that when an incoming signal via the communication chip (BLE) is sent to replace the programming, or part of the programming, on the MCU or MCUs, it acts to replace the VLC ID emitted with a new VLC ID. It is also possible to replace or alter the method by which the signal is modulated by this same mechanism.

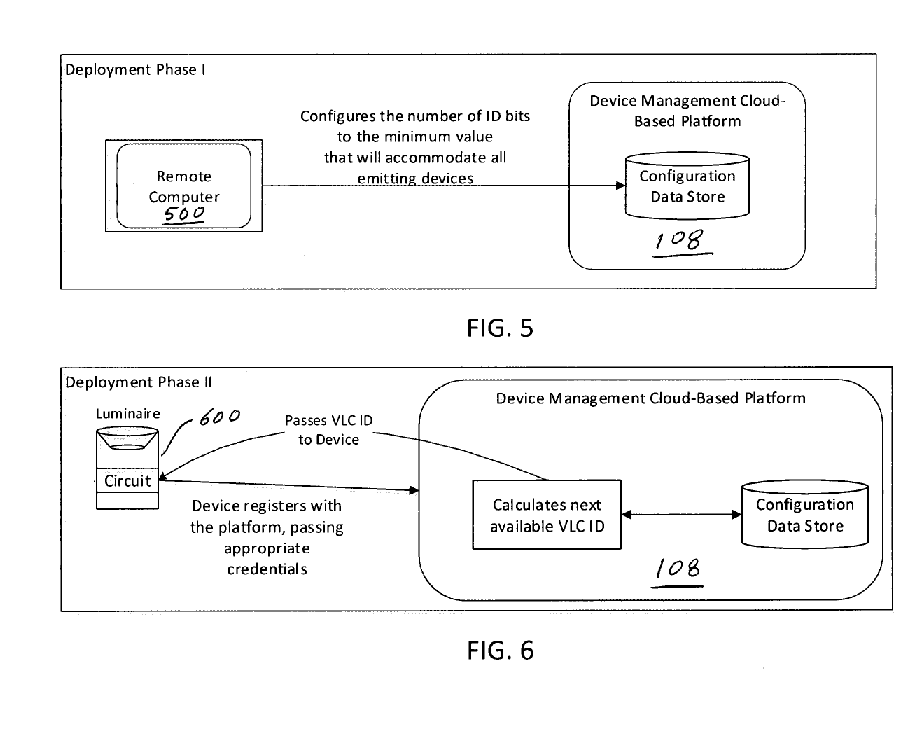

FIG. 5 illustrates a deployment scenario that is initiated from a computer 500 to the platform 108, where a configuration of the system is using a setting corresponding to the least number of bits of the VLC ID that will accommodate all emitting devices in a location. For example, if sixty-four luminaire devices are to be used at a location, it is necessary only that six bits be used to provide a unique VLC ID for each luminaire device.

In FIG. 6, as a new luminaire device 600 registers with platform 108, a new VLC ID is calculated in the form of and having the number of bits stored in FIG. 5, and sent back to the luminaire device 600 where it is stored in persistent storage within the device, and continually emitted when luminaire device 600 is illuminated.

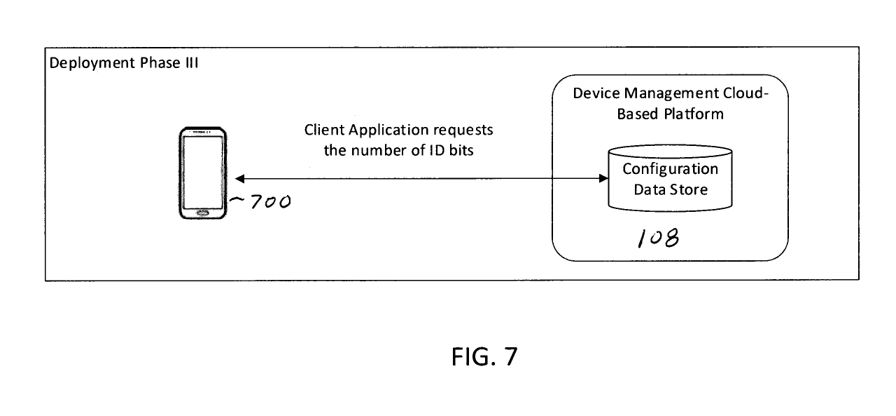

In FIG. 7, a client application, in this example residing on a mobile phone 700, requests, from platform 108, the number of bits expected in the VLC ID, thus facilitating identification of all assigned VLC IDs, and completing enablement of the circle of software that participates in the modulation and demodulation of the emitted signal. Thus, the least number of bits required for transmission of unique VLC IDs within a single deployment has been achieved, allowing a higher transmit rate of VLC IDs per unit of time. The accuracy and speed with which the VLC IDs are recognized is greatly enhanced.

At any time, a managerial user of the cloud platform may control the IDs to clear them all (i.e. setting the IDs to all 0s or 1s), to cease transmission altogether, or to commence transmission of IDs. There are no additional costs related to initiation or ending of the service provided to an end customer. Light fixture VLC IDs may be controlled individually, in groups, or en masse. Similarly, should there be a perceived benefit from emitting IDs from only subsets of luminaire devices, this can be accomplished as readily.

Replacement of malfunctioning luminaire devices presents no significant burden, as the old ID can be reused by pushing it down to the luminaire device within the new light fixture.

As luminaires are moved from one location to another, or if for some other reason it is perceived beneficial to re-ID the luminaires (for example to easily distinguish between data related to the luminaire collected before and after the manipulation of the ID), it is possible to do so with little effort.

Deployment

A specific approach to the use of a VLC ID is to improve the efficiency with which the network addresses of networked light-emitting devices can be recognized during a deployment. During deployment this can be used to understand which device, as defined by its address on a mesh network, is located where, physically. Alternate ways this could be achieved, for instance, is by printing an identifier on the device hardware, or by displaying it in a digital display; however, this and other similar methods typically require immediate access to the device, and accordingly have short-comings in many settings where the placement of the device is within anything but immediate reach; for example on a pole, tower or high ceiling.

While it is theoretically possible to provide this feature with static VLC IDs, the coordination effort required to map the network node addresses and the VLC IDs is significant, and in some cases, where secure addressing is not assigned to meshed network nodes during manufacture but during the subsequent deployment phase, altogether impossible. Malleable and remote controllable VLC IDs make this possible.

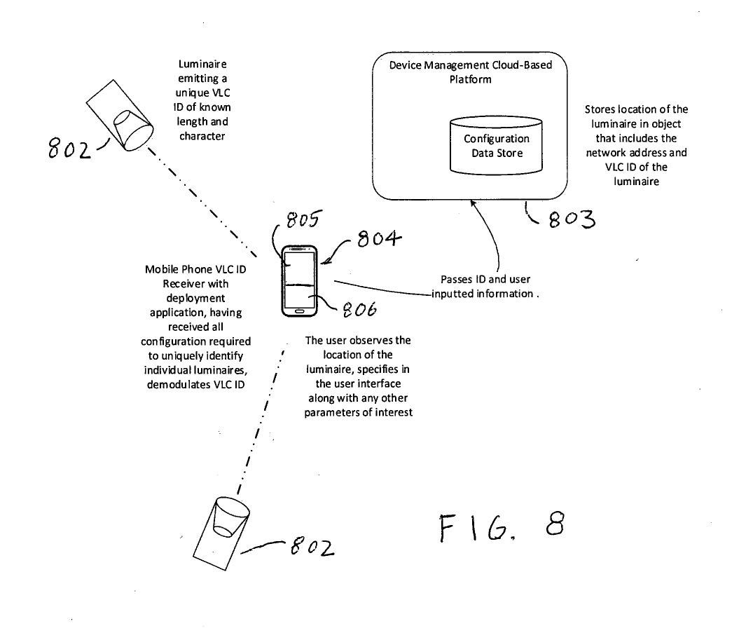

With reference to FIG. 8, to accomplish this, the following typical manufacture and deployment scenario is envisioned. A set of devices 802 capable of emitting VLC IDs and of attaching to a network mesh are created during the manufacturing phase, without specific IDs and without specific network addresses. During the deployment phase the set of devices are networked together and assigned networking addresses. They then may register and connect to a remote computing system 803, having, for example, a device management cloud-based platform, from which they can be controlled via a gateway (not shown in FIG. 8). During this time the network addresses of devices 802 and other properties are stored on the remote system, and security credentials may be exchanged. As part of the deployment, devices 802 are also placed in physical space. At this time it is known to the system topologically where the devices are located in relation to one another, and how they are connected and may be addressed, but not where the devices are located in physical space. The remote system may at this time instruct the VLC ID-emitting devices 802 to emit an ID corresponding to the network address. For these purposes, an application has been created for mobile devices such as a tablet or telephone 804, capable of detecting the emitted ID of devices 802 by use of the camera on the device or telephone 804, of communicating with the remote system 803, of presenting a map of the deployment space to its user on the display panel 805 of device or telephone 804, and a facility, such as a key pad 806 of device or telephone 804, whereby a user may specify the location of any given device. By pointing the camera of device or telephone 804 toward a specific VLC ID-emitting device 802, its ID is detected, and printed on the screen or display panel 805 of device or telephone 804. One significant benefit of this method over other radio-wave emission-based systems that could be designed for the same purpose is that to a human it is intuitively obvious which light is pointed at and detected by the camera, even at a great distance. Further the degree of accuracy of the system in settings where lights are deployed very densely can be anticipated. Once the ID is detected, the user specifies the location on the map on display panel 805 where the device corresponding to the networking address is located. The placement and ID information is transmitted to remote system 803, where the location parameters are associated with the data of the device 802 defined by its network address, known because it is the emitted VLC ID. The user continues this action until all devices have been placed on the map, at which time the deployment phase may be considered complete, and after which subsequent IDs emitted by the devices can be rearranged to accommodate any other purpose.

There are variations to this scenario that build on the same idea. For example, instead of emitting the network address, any unique ID for which there is a 1:1 mapping of the ID to the networked node address can be used. A mapping application can in that case instead of directly using the networked node address, first look up that address in a database that contains mappings of all networked nodes and VLC IDs. Further, the type of network connecting the devices together may not be a mesh but of some other topology. Other modes of communication can be used. It is possible to assign IDs during manufacturing instead of during the deployment phase. The primary function of the devices themselves may be as lights or luminaires, but they can also be some other type of device, while including a light capable of emitting a VLC ID. It is possible for the devices 802 to be connected directly to the remote computing system 803, as shown in FIG. 8, instead of via a gateway; the remote computing system may be housed in the local facility or in a facility far away. Instead of a camera detecting the light pulses that constitute the ID, other light-sensitive sensors may be used.

It is not only the ID that can be passed down but also the modulation (including any encoding and/or encryption) scheme applied to the signal. Alternatively, the modulation scheme can be altered by pushing down a new modulation scheme in the form of microcontroller software to the circuitry within the luminaire devices. When this is the case, applications at the receiving end will need to be updated as well, which can be performed the next time the luminaire devices connect with the platform.

LED Based ID Emitters Used For Multifactor Authentication

Authentication factors describe a category of credentials intended to verify that the identity of an individual or a system is what they declare themselves to be. Knowledge factors represent something a user or a system “knows”, while possession factors represent something one “has”, such as a mobile phone; other types include inherence factors, things one “are” such as a fingerprint. The purpose of all such factors is to ultimately deliver one or more “authentication data”, pieces of information, to an authenticating system. Authentication accomplished by a combination of multiple factors, and in particular multiple factors of different types, is more secure than single-factor authentication. The present disclosure presents a new type of possession authentication factor: a VLC ID-emitting LED light source. The receiver of the VLC ID may be a camera-based mobile phone or other device, or a device equipped with a light sensitive sensor of a different type. The VLC ID in this context constitutes the authentication data, or an encrypted and/or encoded version thereof.

A light as an authentication factor include some characteristics differentiating it from existing factors:
Remote delivery of the corresponding authenticating data (as far as the emitted light can be discerned by the receiver);
Authenticating data delivery over a channel whose reach is intuitively grasped by a human (wherever the light reaches);
Authenticating data delivery over a location that usually can be easily secured (by limiting the reach of the light);
Authenticating data delivery over a channel that can be shared among multiple users or limited to a single user;
Authenticating data delivery over a fixed physical location reaching a large area or as a narrowly focused beam, or as a small portable device;
Authenticating data delivery that in many cases require no human interaction.

With these unique features of unobtrusiveness, ease of use, security, flexibility with respect to size of the delivery mechanism, and ability to be shared with others in a controlled manner, application of multi-factor authentication can be broadened, and in many cases simplified. In a simple scenario of logging in to an email account, instead of a user transferring authentication data delivered to their mobile phone as a text message from the authentication management system (a method which indicates that the user also “has” the phone to which the text was delivered), the transfer of VLC ID authentication data emitted from a light can proceed without user intervention, thus simplifying the process. Multiple users, for instance workers belonging to the same company, can simultaneously share the light emanating from a single luminaire to which their group of identities has been tied, each user authenticating unobtrusively and automatically to the same system, each individual considered to “have” the light by being in its presence. Similarly, an easily portable “pen-light” LED can be used as a second factor when authenticating secure connections made by mobile phones or other devices where dongles, a possible multi-authentication factor alternative with specific physical port types, may not be supported by the receiving device, or where shining the pen-light into the device is considered preferable for other reasons such as ease of use. Android phones and iOS phones with dissimilar physical ports may all use the same authenticating device where the camera on the phones is all that is required to receive the authentication data.

The luminaire device may be connected to a network or operate without a network connection, with implications for how the authentication data to be delivered is calculated and distributed. On a network, it may be connected to the same or a different network from which other identification factors are delivered to the authenticating system. These two types, in-band and out-of-band authentication, have different security implications, but their use may be mandated by circumstances or considerations of best practice and is not a choice relevant to the present disclosure.

The authentication data itself may be delivered from a remote server that synchronizes information, or be calculated on-board the controlling electronics of the luminaire device itself using shared secret data (exchanged during manufacturing or deployment) and a counter (or time value), or an equivalent method.

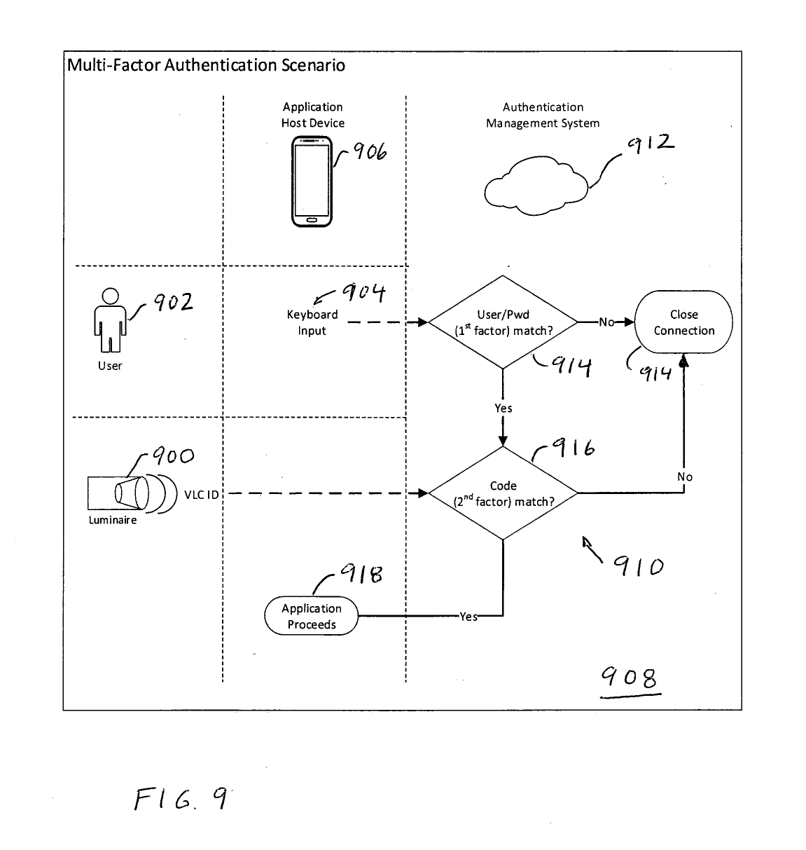

FIG. 9 represents a common multi-factor authentication scenario employing a first factor of a username and password combination, and a second factor of a VLC ID emitted by a luminaire such as VLC 900. The first factor identifies that the user 902 knows the user ID/password combination, as entered by way of keyboard input 904 of a mobile telephone 906. The second factor is that the user “has” the light. An application the user accesses on the mobile phone 906 is given permission to proceed by the authentication management system 908 including hardware or preferably software logic 910 running on a cloud-resident computer 912), only if both factors match expected values of the same stored or calculated by the authentication management system 908. In this example, both the user ID/password are delivered to the cloud server from the same mobile device, but the design of the system is such that the VLC ID could only have been emitted from the VLC 900, of which the user of the mobile phone therefore could be said to be in possession. Before transmission to the authentication management system 908, the authentication data is extracted from the VLC ID by software on the receiving device (in this case the mobile telephone 906), which detects and decodes and/or decrypts the signal as necessary; this may be performed by the methodology described in provisional patent application Ser. No. 62/357,181 entitled Multi-Transmitter VLC Positioning System for Rolling-Shutter Receivers (which is incorporated herein by reference, in its entirety, for all purposes), but can also be substituted for by equivalent methods for cameras or even light-sensitive devices of other types.

At 914, software logic 910 tests whether the user ID and password entered by the user are correct. If the user ID and password are not correct, the user is not connected, as represented by the connection being closed at 914. If the user ID and password are correct, at 916, a determination is made as to whether the authentication data from the VLC 900 is correct. If the authentication data is correct, the connection is made and the user can proceed with the application at 918. If the authentication data is not correct, the user is not connected, as represented by the connection being closed at 914.

Below, two possible scenarios describe how the system may be designed so that the VLC ID-emitted authentication data can be known to have been emitted from a particular luminaire. Variations on these two scenarios exist, including more elaborate features that augment the security of the system.

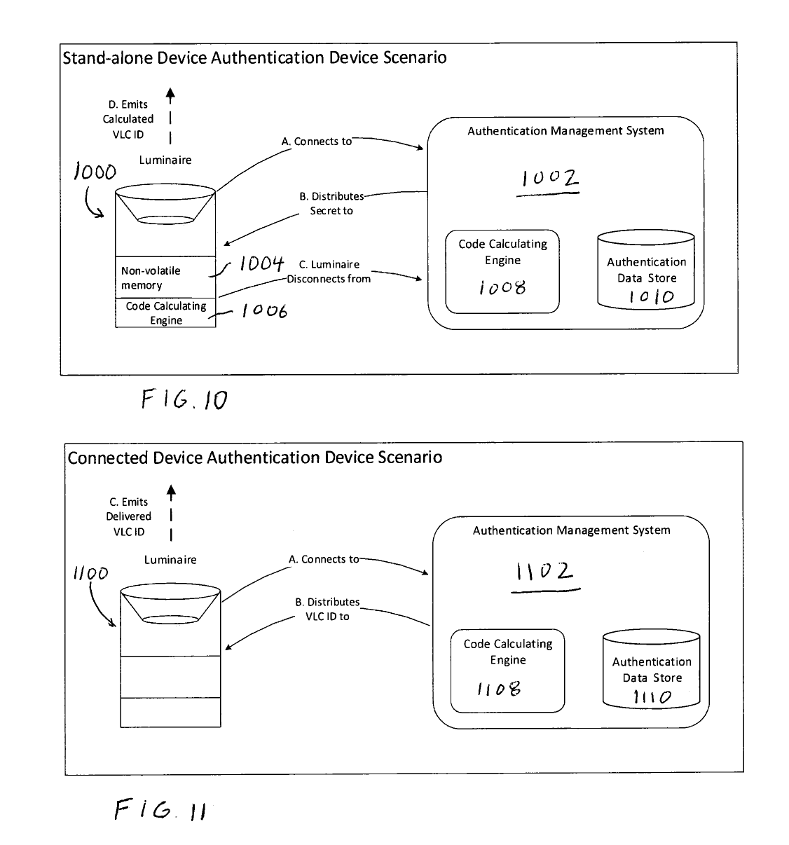

FIG. 10 depicts a stand-alone device authentication scenario, where the luminaire device 1000 is not connected to a network, at least on a persistent basis. Here, a connection to the authentication management system is required only for a brief period, while an initial exchange of a “secret” is carried out. Note that “connected to” the remote system can include a user delivering by hand the information from one system to the other (for instance, by reading the secret from a computer screen display delivered to it by the authentication management system 1002, and typing the secret into a simple display (not shown) on the luminaire device 1000). The secret is stored in non-volatile memory 1004 on the luminaire device 1000, which applies an algorithm into which the secret and either a time-based counter or the current time constitute the inputs to generate the authentication data in a code calculating engine 1006. The authentication data is recalculated on an interval known to both the luminaire device 1000 and authentication management system 1002, such as, for example, once a minute. During the following minute, the authentication data or an encoded/encrypted form thereof is emitted as the VLC ID by luminaire device 1000. Authentication data for a series of luminaires can be stored in an authentication data store 1010.

The authentication management system 1002 includes a code calculating engine 1008 and an authentication data store 1010. The code calculating engine 1008 generates the same authentication data as that calculated by code calculating engine 1006 of luminaire device 1000. Known algorithms may be used for the calculating engine. For example, Google uses an algorithm called “Time-based One-time Password Algorithm”, constructed such that without the secret (which is an arbitrary byte string) a “code” or authentication data cannot be calculated. A reason for why it is continually updated is to reduce the time window for “guesses” and the time during which transfer of the code must occur if it is “gleaned” by other means (for example, looking over someone's shoulder surreptitiously).

FIG. 11 depicts a connected device authentication scenario, where the luminaire device 1100 is not connected to a network; at least not on a persistent basis. Here, the authentication data itself is delivered on some interval determined by the authentication management system 1102 to the connected luminaire device 1100, ideally over an encrypted channel, with the luminaire device 1100 retransmitting the authentication data or an encoded/encrypted form thereof is emitted as the VLC ID. Authentication management system 1102 includes a code calculating engine 1108. Authentication data for a series of luminaires can be stored in an authentication data store 1110.

It is noted that when a persistent and secure delivery mechanism from the authenticating system exists, there is no need for a code calculating engine on the luminaire, as in that case the authenticating data is sent directly from the authenticating system to the luminaire in real time. In that case the code generating engine could be as simple as a random number generator, or similar generator, of any complexity.

The techniques described herein are exemplary, and should not be construed as implying any particular limitation on the present disclosure. It should be understood that various alternatives, combinations and modifications could be devised by those skilled in the art. For example, steps associated with the processes described herein can be performed in any order, unless otherwise specified or dictated by the steps themselves. The present disclosure is intended to embrace all such alternatives, modifications and variances that fall within the scope of the appended claims.

The terms “comprises” or “comprising” are to be interpreted as specifying the presence of the stated features, integers, steps or components, but not precluding the presence of one or more other features, integers, steps or components or groups thereof.

What is claimed is:

1. A apparatus comprising:
a luminaire;
a power input for the luminaire;
a modulation circuit for modulating the power input to the luminaire so that light output of the luminaire includes an identifier of the luminaire; and
a programmable memory within the modulation circuit for storing at least one of the identifier of the luminaire and a modulation scheme for modulation of the luminaire to place a signal on light emitted by the luminaire.

2. The apparatus of claim 1, wherein the identifier is in the form of digital information.

3. The apparatus of claim 1, in combination with a number of other apparatus in accordance with claim 1 at a given location, wherein the digital information of the identifier includes a sufficient number of bits so that each apparatus has a unique identifier.

4. The apparatus of claim 3, wherein the number of bits is no larger than required so that the identifier includes a sufficient number of bits for each apparatus to have a unique identifier.

5. The apparatus of claim 1, further comprising a communications circuit for communication between the modulation circuit and an external platform, so that the external platform can perform at least one of storing the identifier, and communicating with the modulation circuit to perform at least one of providing the identifier to the apparatus, changing the identifier of the apparatus, removing the identifier of the apparatus and modifying the modulation scheme.

6. The apparatus of claim 5, wherein modifying the modulation scheme includes at least one of turning on modulation with the identifier, turning off modulation with the identifier, and changing an encoding or encryption scheme of the modulation.

7. The apparatus of claim 1, wherein the modulation circuit includes at least one microcontroller.

8. The apparatus of claim 1, wherein the power input to the luminaire includes a constant current source.

9. The apparatus of claim 1, wherein the luminaire comprises a light emitting diode.

10. A method for modulating light from a luminaire, comprising:
storing in a programmable memory at least one of an identifier for the luminaire, the identifier being used to modulate the light, and a modulation scheme for modulation of the luminaire; and
changing content of the programmable memory to change at least one of the identifier and the modulation scheme.

11. The method of claim 10, wherein the identifier is in the form of digital information.

12. The method of claim 11, wherein a number of luminaires are at a given location, wherein the digital information of the identifier includes a sufficient number of bits so that each luminaire has a unique identifier.

13. The method of claim 12, wherein the number of bits is no larger than required so that the identifier includes a sufficient number of bits for each luminaire to have a unique identifier.

14. The method of claim 10, further comprising the luminaire communicating with an external platform, so that the external platform can perform at least one of storing the identifier, providing the identifier to the luminaire, changing the identifier of the luminaire, removing the identifier of the luminaire and modifying the modulation scheme.

15. The method of claim 14, wherein modifying the modulation scheme comprises at least one of turning on modulation with the identifier, turning off modulation with the identifier, and changing any encoding or encryption scheme of the modulation.

16. The method of claim 10, wherein power input to the luminaire includes a constant current source.

17. The method of claim 10, wherein the luminaire comprises a light emitting diode.

18. A method for programming modulation circuitry of luminaires at a location, comprising:
selecting a number of identification bits required so that all luminaires have a unique identifier;
registering the luminaires so that each luminaire has one of the unique identifiers; and
providing at least one of the number of identification bits to a receiver so that the receiver can recognize the identifiers and particulars about the modulation scheme that is used by the luminaires so that the receiver can demodulate the signal.

19. The method of claim 18, wherein the number of bits is no larger than required so that the identifier includes a sufficient number of bits for each luminaire to have a unique identifier.
